(19) United States
(12) Patent Application Publication
(10) Pub. No.: US 2025/0370004 A1
(43) Pub. Date: Dec. 4, 2025

(54) TRACKER FOR ELECTRICAL WIRES AND USE THEREOF

(71) Applicant: Valance Electric Services, Surrey (CA)

(72) Inventor: Ryan O'Connor, Surrey (CA)

(73) Assignee: Valance Electric Services, Surrey (CA)

(21) Appl. No.: 19/221,692

(22) Filed: May 29, 2025

(30) Foreign Application Priority Data
May 29, 2024 (CA) 3240015

(51) Int. Cl. G01R 1/04; G01R 31/08; G01R 31/58

(52) U.S. Cl. CPC G01R 1/0416; G01R 31/081; G01R 31/58

(57) ABSTRACT

A intermittent load generator for tracking an electrical wire, the wire tracker including: a housing; an electrical cable extending outward from the housing to an ambient environment; a plug which is in electrical communication with the electrical cable; an indicator light which is retained on the housing and is in electrical communication with the electrical cable; one or more resistors which are housed in the housing and are in electrical communication with the electrical cable; and a switch which is in electrical communication with the one or more resistors, is housed in the housing and is configured to switch the one or more resistors on and off in oscillations with a period of 0.05 seconds to 120 seconds.

### CROSS REFERENCE TO RELATED APPLICATIONS

The present application claims benefit of Canadian Patent Application Serial No. 3,240,015 filed May 29, 2024, and entitled TRACKER FOR ELECTRICAL WIRES AND USE THEREOF, the contents of which are incorporated herein by reference.

### FIELD

The present technology is directed to an accurate and easy to use wire tracker. More specifically, it is a wire tracker that adds pulses of increased electrical resistance to the selected circuit that alters the electrical current and is detectable with a standard clamp-on meter.

### BACKGROUND

Traditional electrical tracing of copper cables is accomplished by connecting a radio frequency (RF) tone generator to one or two electrical conductors to energize the cable with a sinusoidal or square wave sound signal in the frequency range of 500 Hz to 3 kHz. A weak electromagnetic signature at this characteristic frequency is radiated along the entire length of the wire, whereby the wire functions as an extended wire antenna in which the surrounding environment provides a common ground. This RF signal transmits through non-conductive walls, floors and ceilings with minimal signal strength attenuation and is detected by a wireless, handheld RF tone detector. A tone detector typically includes a voltage probe that emits an audible tone when placed in the vicinity of a cable carrying the tone. This method of voltage tone detection is the standard for tracking electrical cables. Unfortunately, this method is known to be inaccurate, with an estimated 70-85% accuracy. Further, a user may not be able to hear the tone detector in noisy environments. These deficiencies lead to poor efficiency, which when dealing with large panels can waste a considerable amount of an electrician's time.

United States Patent Application Publication No. 20120219259 discloses composite fiber optic cables having exposed, conductive traces external to the cable jacket enable non-invasive, wireless electrical tone tracing of fiber optic cables. The cross-sectional geometry of the fiber optic cable prevents conductive traces from short circuiting when abutting other cables or grounded conductive elements. Moreover, the structure allows convenient electrical contact to the conductive traces at any location along the longitudinal extent of the cable without requiring penetration of the cable jacket or removal of fiber optic connectors. Traceable fiber optic cables of various types are disclosed, including simplex, duplex and ribbon cables. Systems of traceable cables utilizing connectors with integrated electrical antenna elements attached to the conductive elements of cable and RFID tags for remote connector port identification are further disclosed.

U.S. Pat. No. 8,396,603 discloses an irrigation controller, method and software program product for generating wire tracker signal transmission across a control wire. The irrigation controller includes a valve actuation control module selectively coupled to each of a plurality of control wires and generating a valve actuation control signal thereon. The valve actuation control signal is a continuous control voltage over a plurality of control signal periods for selectively energizing the selected irrigation valve. Also integrated in the irrigation controller is a wire tracker transmitter module for selectively coupling to each of a plurality of control wires and generating a transmission signal that can be received at a mobile receiver. Wire tracker circuit generally comprises normally closed switch that, when activated, safely decouples irrigation control signal input from the control wire, or from irrigation control wire selector, while simultaneously coupling wire tracker transmitter between wire tracker wire selector and auxiliary earth ground.

What is needed is an accurate and easy to use tracker system for electrical wires. It would be preferable if it emitted a visual signal rather than a sound signal. It would be further preferable if the system consisted of an intermittent load generator and a standard clamp meter. It would be preferable if it also could be used with a tone probe or an ohm meter if the wire is de-energized. It would be preferable if the intermittent load generator produced pulses of increased amperage. It would be further preferable if the wire being tracked could be either energized or de-energized.

### SUMMARY

An accurate and easy to use tracker system for electrical wires is provided. It emits a visual signal rather than a sound signal. The system consists of an intermittent load generator and a standard clamp meter. In an alternative embodiment, a tone probe may be used. In yet another embodiment, an ohm meter may be used. The intermittent load generator produces pulses of increased amperage by increasing resistance. The wire being tracked can be either energized or not energized, depending on the sensor being used.

In one embodiment, a intermittent load generator is provided for tracking an electrical wire, the intermittent load generator including: a housing; an electrical cable extending outward from the housing to an ambient environment; a plug which is in electrical communication with the electrical cable; an indicator light which is retained on the housing and is in electrical communication with the electrical cable; one or more resistors which are housed in the housing and are in electrical communication with the electrical cable; and a switch which is in electrical communication with the one or more resistors, is housed in the housing and is configured to switch the one or more resistors on and off in oscillations with a period of 0.05 seconds to 120 seconds.

In the intermittent load generator, the one or more resistors may total a resistance of 24 to 2400 ohms.

In the intermittent load generator, the switch may be configured to switch the one or more resistors on and off in oscillations with the period of 60 seconds.

In the intermittent load generator, the switch may be configured to switch the one or more resistors on for twenty seconds and off for ten seconds.

In the intermittent load generator, the intermittent load generator may be configured to increase an amperage by 0.05 amperes to 5 amperes in oscillations with the period of 60 seconds.

In the intermittent load generator, the intermittent load generator may be configured to increase the amperage by 2 amperes in oscillations with the period of 60 seconds.

In another embodiment, a wire tracker system is provided, the wire tracker system including: a sensor which is selected from the group consisting of a tone probe, an ohm meter and a clamp meter; and a intermittent load generator, the intermittent load generator including: a housing; an electrical cable extending outward from the housing to an ambient environment; a plug which is in electrical communication with the electrical cable; an indicator light which is retained on the housing and is in electrical communication with the electrical cable; one or more resistors which are housed in the housing and are in electrical communication with the electrical cable; and a switch which is in electrical communication with the one or more resistors, is housed in the housing and is configured to switch on and off in oscillations with a period of 0.05 seconds to 120 seconds.

In the wire tracker system, the sensor may be a clamp meter.

In the wire tracker system, the switch may be configured to switch the one or more resistors on and off in oscillations with a period of 60 seconds.

In the wire tracker system, the one or more resistors may be configured to provide total of a resistance of 24 to 2400 ohms resistance at the period of 60 seconds.

In the wire tracker system, the intermittent load generator may be configured to increase an amperage by 0.05 amperes to 5 amperes in oscillation at the period of 60 seconds.

In the wire tracker system, the intermittent load generator may be configured to increase the amperage by 2 amperes in oscillations at the period of 60 seconds.

In another embodiment, a method of tracing an electrical wire is provided, the method comprising: a user selecting the system of claim 7; the user plugging the intermittent load generator into an electrical outlet; the user placing the sensor proximate to or on a selected electrical wire; switching, with the switch, the one or more resistors on and off in oscillations with a period of between 0.05 to 120 seconds; the sensor sensing the oscillations; the sensor reporting the selected wire is either a correct wire or an incorrect wire; if the selected wire is the incorrect wire, the user placing the sensor proximate to or on another selected wire until the correct wire is detected, thereby tracing the electrical wire.

In the method, the sensor may be sensing oscillations in amperage at the period of between 0.05 to 120 seconds.

In the method, the sensor may be sensing the oscillations in amperage with an amplitude of between 0.05 amperes to 5 amperes.

In the method, the amplitude may be 2 amperes.

In the method, the electrical wire may be loaded with an amperage of 10 amperes and the amperage may be increased to 12 amperes when the one or more resistors are on.

In the method, the sensor may be a clamp meter.

In the method, the sensor may be a tone probe.

In the method, the sensor may be an ohm meter.

### FIGURES

FIG. 1 is a schematic of the system of the present technology.

FIG. 2 is a schematic of an alternative embodiment of FIG. 1.

FIG. 3 is a schematic of an alternative embodiment of FIG. 1.

FIG. 4A is a schematic of the intermittent load generator of the system of FIG. 1; and FIG. 4B is a schematic of the intermittent load generator along line B-B.

FIG. 5 is a graph of an exemplary signal.

FIG. 6 is a block diagram of the method of the present technology.

### DESCRIPTION

Except as otherwise expressly provided, the following rules of interpretation apply to this specification (written description and claims): (a) all words used herein shall be construed to be of such gender or number (singular or plural) as the circumstances require; (b) the singular terms “a”, “an”, and “the”, as used in the specification and the appended claims include plural references unless the context clearly dictates otherwise; (c) the antecedent term “about” applied to a recited range or value denotes an approximation within the deviation in the range or value known or expected in the art from the measurements method; (d) the words “herein”, “hereby”, “hereof”, “hereto”, “hereinbefore”, and “hereinafter”, and words of similar import, refer to this specification in its entirety and not to any particular paragraph, claim or other subdivision, unless otherwise specified; (e) descriptive headings are for convenience only and shall not control or affect the meaning or construction of any part of the specification; and (f) “or” and “any” are not exclusive and “include” and “including” are not limiting. Further, the terms “comprising,” “having,” “including,” and “containing” are to be construed as open-ended terms (i.e., meaning “including, but not limited to,”) unless otherwise noted.

Recitation of ranges of values herein are merely intended to serve as a shorthand method of referring individually to each separate value falling within the range, unless otherwise indicated herein, and each separate value is incorporated into the specification as if it were individually recited herein. Where a specific range of values is provided, it is understood that each intervening value, to the tenth of the unit of the lower limit unless the context clearly dictates otherwise, between the upper and lower limit of that range and any other stated or intervening value in that stated range, is included therein. All smaller sub ranges are also included. The upper and lower limits of these smaller ranges are also included therein, subject to any specifically excluded limit in the stated range.

Unless defined otherwise, all technical and scientific terms used herein have the same meaning as commonly understood by one of ordinary skill in the relevant art. Although any methods and materials similar or equivalent to those described herein can also be used, the acceptable methods and materials are now described.

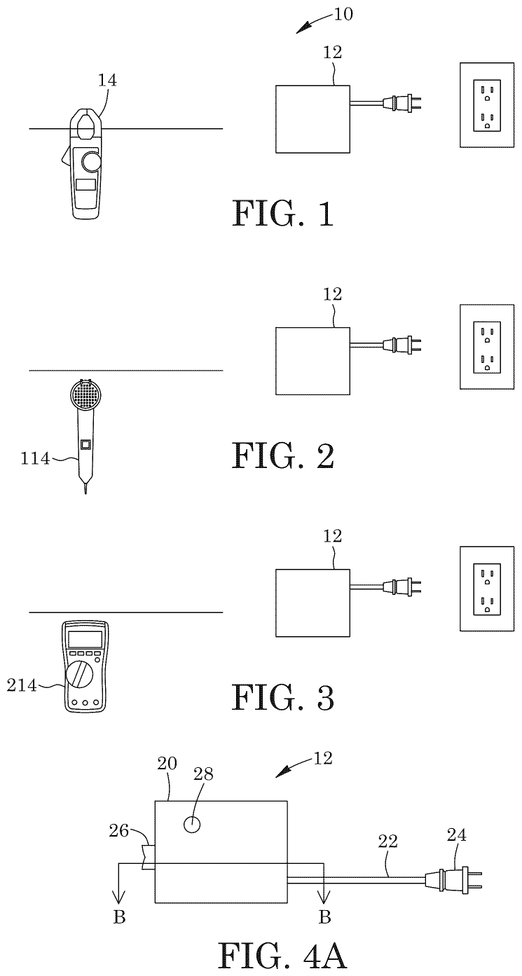

A wire tracker system, generally referred to as 10 is shown in FIG. 1. It includes a intermittent load generator 12 and a clamp meter 14 as the sensor. It can be seen that the intermittent load generator 12 plugs into a wall socket and the clamp meter 14 clamps around an electrical wire. In this embodiment, the electrical wires being traced are energized. In an alternative embodiment, shown in FIG. 2, the system 110 includes the intermittent load generator 12 and a tone probe 114 as the sensor. In this embodiment, the electrical wires being traced are energized. In yet another embodiment, shown in FIG. 3, the system 210 includes the intermittent load generator 12 and an ohm meter 214 as the sensor. In this embodiment, the electrical wires being traced are either energized or are not energized.

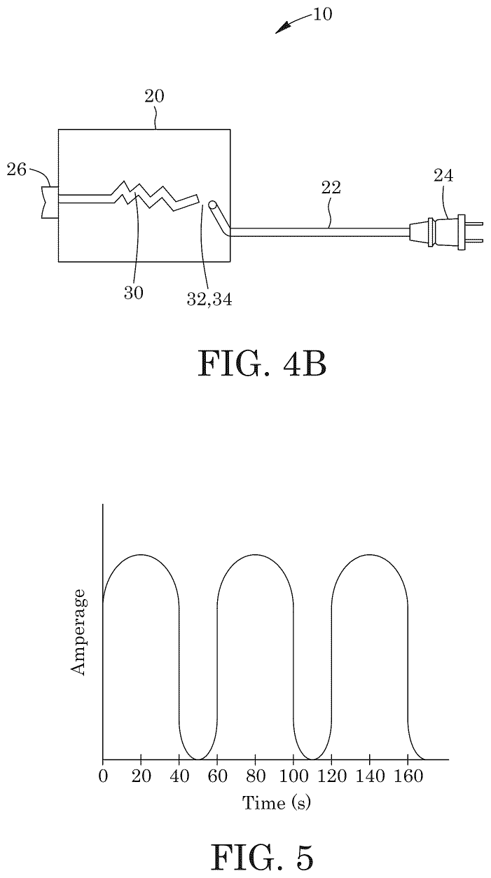

As shown in FIG. 4A, the intermittent load generator, generally referred to as 12 includes a housing 20, an electrical cable 22, a plug 24, an on/off switch 26 which is in electrical connection with the electrical cable 22 and an indicator light 28 which is in electrical communication with the on/off switch. As shown in FIG. 4B, housed in the housing 20 is at least one resistor 30, and a controller 32, which includes a timer 34. In one embodiment, the controller 32 is a switch that switches on and off at a set time interval. In another embodiment, the controller is a microcontroller. The preferred time “on” is about 0.05 to about 120 seconds and the preferred time “off” is about 0.05 to about 120 seconds. Thus, the period of the oscillations is about 0.05 seconds to 120 seconds. In one embodiment the time “on” is equal to the time “off”. In another embodiment, the time off is greater than the time on. In yet another embodiment, the time “on” is greater than the time “off”. In one embodiment, the indicator light 28 is not included as the sensor 214 is an ohm meter and can be used on electrical wires that are not energized.

As shown in FIG. 5, a preferred embodiment the oscillations have a period of about 60 seconds, with the time “on” being about 40 seconds. The increase in amperage is between about 0.05 and 5 amperes, with a preferred amperage increase being about 2 amperes. The resistance is provided by a resistor that provides between about 2400 to 24 ohms.

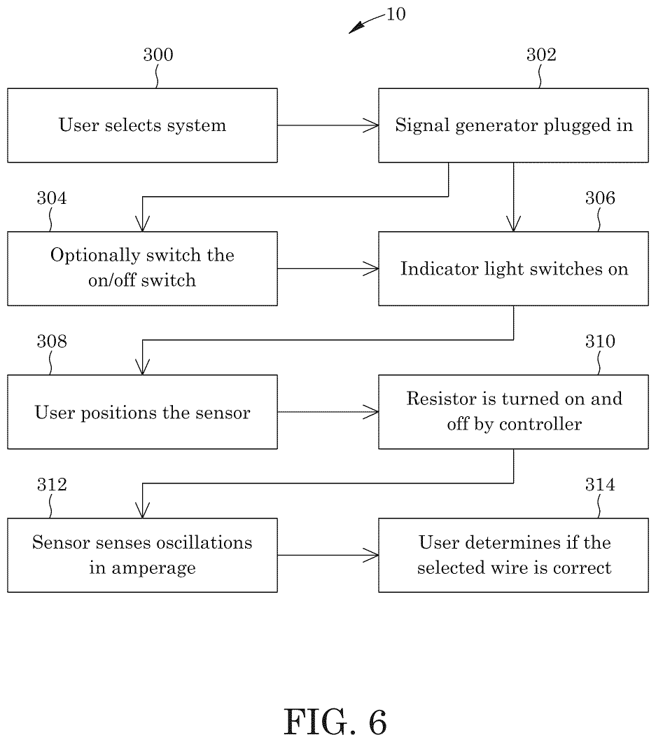

The method of operating the system is shown in FIG. 6 and is as follows: a user selects 300 the system 10; they plug 302 the intermittent load generator 12 into an electrical outlet; they optionally switch 304 the intermittent load generator 12 on; the indicator light turns 306 on when the system is used on an energized wire and does not turn on when used on a wire that is not energized (this is specific to using an ohm meter as the sensor); the user places 308 the sensor 14 proximate to or on the electrical wire to be tested; the switch 32 turns 310 the resistor 30 on and off in oscillations with a period of between 0.05 seconds to 120 seconds; the sensor 14 senses 312 the oscillations which are oscillations in amperage between the amperage load of the electrical wire and an added increase of 0.05 amperes to 5 amperes; and the user determines 314 whether or not the electrical wire is the correct electrical wire. The electrical wire may be loaded at 12 amperes for a 15-ampere breaker and the intermittent load generator increases that amperage to 14 amperes when the one or more resistors are switched “on”. Without being bound to theory, the amperage load for the 15-ampere breaker may be as high as 17 or 18 amperes transiently.

While example embodiments have been described in connection with what is presently considered to be an example of a possible most practical and/or suitable embodiment, it is to be understood that the descriptions are not to be limited to the disclosed embodiments, but on the contrary, is intended to cover various modifications and equivalent arrangements included within the spirit and scope of the example embodiment. Those skilled in the art will recognize or be able to ascertain using no more than routine experimentation, many equivalents to the specific example embodiments specifically described herein.

1. A intermittent load generator for tracking an electrical wire, the intermittent load generator including: a housing; an electrical cable extending outward from the housing to an ambient environment; a plug which is in electrical communication with the electrical cable; one or more resistors which are housed in the housing and are in electrical communication with the electrical cable; and a switch which is in electrical communication with the one or more resistors, is housed in the housing and is configured to switch the one or more resistors on and off in oscillations with a period of 0.05 seconds to 120 seconds.

2. The intermittent load generator of claim 1, further comprising an indicator light which is retained on the housing and is in electrical communication with the electrical cable.

3. The intermittent load generator of claim 2, wherein the one or more resistors total a resistance of 24 to 2400 ohms.

4. The intermittent load generator of claim 3, wherein the switch is configured to switch the one or more resistors on and off in oscillations with the period of 60 seconds.

5. The intermittent load generator of claim 4, wherein the switch is configured to switch the one or more resistors on for twenty seconds and off for ten seconds.

6. The intermittent load generator of claim 4, wherein the intermittent load generator is configured to increase an amperage by 0.05 amperes to 5 amperes in oscillations with the period of 60 seconds.

7. The intermittent load generator of claim 6, wherein the intermittent load generator is configured to increase the amperage by 2 amperes in oscillations with the period of 60 seconds.

8. A wire tracker system, the wire tracker system including: a sensor which is selected from the group consisting of a tone probe, an ohm meter and a clamp meter; and a intermittent load generator, the intermittent load generator including: a housing; an electrical cable extending outward from the housing to an ambient environment; a plug which is in electrical communication with the electrical cable; one or more resistors which are housed in the housing and are in electrical communication with the electrical cable; and a switch which is in electrical communication with the one or more resistors, is housed in the housing and is configured to switch on and off in oscillations with a period of 0.05 seconds to 120 seconds.

9. The wire tracker system of claim 8, wherein the sensor is a clamp meter.

10. The wire tracker system of 9, wherein the switch is configured to switch the one or more resistors on and off in oscillations with a period of 60 seconds.

11. The wire tracker system of claim 10, wherein the one or more resistors are configured to provide total of a resistance of 24 to 2400 ohms resistance at the period of 60 seconds.

12. The wire tracker system of claim 11, wherein the intermittent load generator is configured to increase an amperage by 0.05 amperes to 5 amperes in oscillation at the period of 60 seconds.

13. The wire tracker system of claim 12, wherein the intermittent load generator is configured to increase the amperage by 2 amperes in oscillations at the period of 60 seconds.

14. The wire tracker system of claim 13, wherein the intermittent load generator further comprises an indicator light which is retained on the housing and is in electrical communication with the electrical cable.

15. A method of tracing an electrical wire, the method comprising: a user selecting the system of claim 8; the user plugging the intermittent load generator into an electrical outlet; the user placing the sensor proximate to or on a selected electrical wire; the intermittent load generator switching, with the switch, the one or more resistors on and off in oscillations with a period of between 0.05 to 120 seconds; the sensor sensing the oscillations; the sensor reporting the selected electrical wire is either a correct electrical wire or an incorrect electrical wire; if the selected electrical wire is the incorrect electrical wire, the user placing the sensor proximate to or on another selected electrical wire until the correct electrical wire is detected, thereby tracing the electrical wire.

16. The method of claim 15, wherein the sensor is sensing oscillations in amperage at the period of between 0.05 to 120 seconds.

17. The method of claim 16, wherein the sensor is sensing the oscillations in amperage with an amplitude of between 0.05 amperes to 5 amperes.

18. The method of claim 17, wherein the amplitude is 2 amperes.

19. The method of claim 16, wherein the electrical wire is loaded with an amperage of 12 amperes and the amperage increased to 12 amperes when the one or more resistors are on.

20. The method of claim 19, wherein the sensor is a clamp meter.
